(19) United States
(12) Patent Application Publication
(10) Pub. No.: US 2026/0106450 A1
(43) Pub. Date: Apr. 16, 2026

(54) SYSTEM AND METHOD FOR MONITORING LIQUID COOLANT IN AN INFORMATION HANDLING SYSTEM

(71) Applicant: DELL PRODUCTS L.P., Round Rock, TX (US)

(72) Inventor: Nicholas Esposito, Round Rock, TX (US)

(21) Appl. No.: 18/914,935

(22) Filed: Oct. 14, 2024

(51) Int. Cl. H02H 5/08; G01M 3/04; G06F 1/3206; H05K 7/20

(52) U.S. Cl. CPC H02H 5/083; G01M 3/04; G06F 1/3206; H05K 7/20254; H05K 7/20272

(57) ABSTRACT

A system is disclosed and includes an optical light source to transmit an initial optical signal through a coolant loop, an optical light sensor to receive an initial optical signal response, and in information handling system. The information handling system includes a memory to communicate with the optical light sensor to store the initial optical signal response and a processor to communicate with the memory and the optical light sensor. The processor determines a current optical signal response through the coolant loop and compares the current optical signal response to the initial optical signal response.

### FIELD OF THE DISCLOSURE

The present disclosure generally relates to information handling systems, and more particularly relates to monitoring liquid coolant in an information handling system.

### BACKGROUND

As the value and use of information continues to increase, individuals and businesses seek additional ways to process and store information. One option is an information handling system. An information handling system generally processes, compiles, stores, or communicates information or data for business, personal, or other purposes. Technology and information handling needs and requirements can vary between different applications. Thus, information handling systems can also vary regarding what information is handled, how the information is handled, how much information is processed, stored, or communicated, and how quickly and efficiently the information can be processed, stored, or communicated. The variations in information handling systems allow information handling systems to be general or configured for a specific user or specific use such as financial transaction processing, airline reservations, enterprise data storage, or global communications. In addition, information handling systems can include a variety of hardware and software resources that can be configured to process, store, and communicate information and can include one or more computer systems, graphics interface systems, data storage systems, networking systems, and mobile communication systems. Information handling systems can also implement various virtualized architectures. Data and voice communications among information handling systems may be via networks that are wired, wireless, or some combination.

### SUMMARY

A system is disclosed and includes an optical light source to transmit an initial optical signal through a coolant loop, an optical light sensor to receive an initial optical signal response, and in information handling system. The information handling system includes a memory to communicate with the optical light sensor to store the initial optical signal response and a processor to communicate with the memory and the optical light sensor. The processor may determine a current optical signal response through the coolant loop and compare the current optical signal response to the initial optical signal response.

### BRIEF DESCRIPTION OF THE DRAWINGS

It will be appreciated that for simplicity and clarity of illustration, elements illustrated in the Figures are not necessarily drawn to scale. For example, the dimensions of some elements may be exaggerated relative to other elements. Embodiments incorporating teachings of the present disclosure are shown and described with respect to the drawings herein, in which:

FIG. 1 is a block diagram of computing system according to an embodiment of the present disclosure;

FIG. 2 is a flow diagram of a method for monitoring liquid coolant in an information handling system according to an embodiment of the present disclosure; and

FIG. 3 is a block diagram of a general information handling system according to an embodiment of the present disclosure.

The use of the same reference symbols in different drawings indicates similar or identical items.

### DETAILED DESCRIPTION OF THE DRAWINGS

The following description in combination with the Figures is provided to assist in understanding the teachings disclosed herein. The description is focused on specific implementations and embodiments of the teachings and is provided to assist in describing the teachings. This focus should not be interpreted as a limitation on the scope or applicability of the teachings.

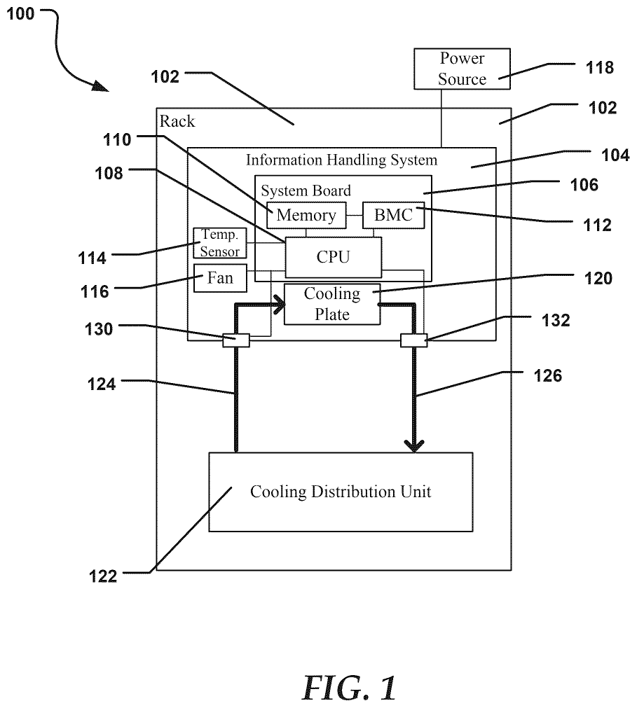

FIG. 1 illustrates a system 100 that may include a rack 102, or cabinet, in which an information handling system 104 is installed, or otherwise disposed. For purposes of this disclosure, an information handling system can include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an information handling system may be a personal computer (such as a desktop or laptop), tablet computer, mobile device (such as a personal digital assistant (PDA) or smart phone), server (such as a blade server or rack server), a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, touchscreen and/or a video display. The information handling system may also include one or more buses operable to transmit communications between the various hardware components.

As shown, the information handling system 104 may include a system board 106, or motherboard, on which a central processing unit (CPU) 108 is installed, or otherwise disposed. The information handling system 104 may also include a memory 110 coupled to the CPU 108. Moreover, a baseboard management controller 112 may be disposed on the system board 106 and may be coupled to the CPU 108 and the memory 110. Other components necessary to the operation of the information handling system 104, and well known in the art, may be disposed on the system board 106. The information handling system 104 may also include a temperature sensor 114, a fan 116 adjacent the CPU 108, and a leak sensor 118. For example, the leak sensor 118 may be an optical light sensor. Additionally, the information handling system 104 may be coupled to a power source 119. The power source 119 may be an alternating current (AC) power source, a direct current (DC) power source, or a combination thereof. The power source 119 may provide power to all of the components described herein that required power to operate.

FIG. 1 further shows a cooling plate 120 adjacent the system board 106. Specifically, the cooling plate 120 is adjacent the CPU 108 which may generate and emit a substantial amount of heat during operation of the information handling system 102. A cooling distribution unit 122 may be connected to the cooling plate 120 via a coolant supply line 124 and a coolant return line 126. An optical signal source 130 may be disposed, or otherwise installed, along the supply line 124 upstream from the cooling plate 120. Moreover, an optical sensor 132 may be disposed, or otherwise installed, along the return line 126 downstream from the cooling plate 120. The optical signal source 130 and the optical sensor 132 may be operable coupled to the CPU or processor 108.

In an example, the optical signal source 130 and the optical sensor 132 may be placed at opposite ends of the liquid loop through the information handling system 104. Based on the locations of both the optical signal source 130 and the optical sensor 132, a transmission path of an optical signal from the optical signal source 130 and the optical sensor 132 may be along an area of concern for possible leaks in the liquid cooling loop. The liquid loop from CDU 122, through the coolant supply line 124, cooling plate 120 and the return line 126, and back to the CDU 122 may be a waveguide for optical signals transmitted between the optical signal source 130 and the optical sensor 132.

In a particular embodiment, the optical signal source 130 may be used to transmit an initial optical signal through liquid coolant within the cooling plate 120 and any associated plumbing, such as the coolant supply line 124 and the return line 126, within the information handling system 104 to the optical sensor 132. Based on this initial optical signal, processor 108 may determine an initial, or nominal, optical signal response within the cooling plate 120 and associated internal plumbing, such as the coolant supply line 124 and the return line 126, within the information handling system 104 based on the luminescence of the liquid coolant when excited by the optical light source 130. The processor 108 may store the initial signal response in the memory 110.

Then, periodically, the optical signal source 130 may be used to transmit a current optical signal through the cooling plate 120 and any associated plumbing, such as the coolant supply line 124 and the return line 126, within the information handling system 104 to the optical sensor 132 in order to determine a current optical signal response within the cooling plate 120 and associated internal plumbing within the information handling system 104. Processor 108 may compare the current optical signal response to the initial optical signal response to determine whether the current optical signal response is transformed relative to the initial optical signal response. The current optical signal response may be considered transformed if the current signal response is phase shifted, attenuated (the signal amplitude is decrease), or a combination thereof. The transformation of the current optical signal response relative to the initial optical signal response may indicate that there is a leak within the cooling plate 120 and the associated plumbing within the information handling system 104 based on a continuous index of refraction along the liquid loop being altered in the current optical signal response as compared to the initial optical signal response.

If the current optical signal response is transformed from the initial optical signal response, processor 108 may include issue a leak alert. Thereafter, processor 108 may also de-energize the information handling system 104 to prevent, or minimize, damage to the internal components of the information handling system 104.

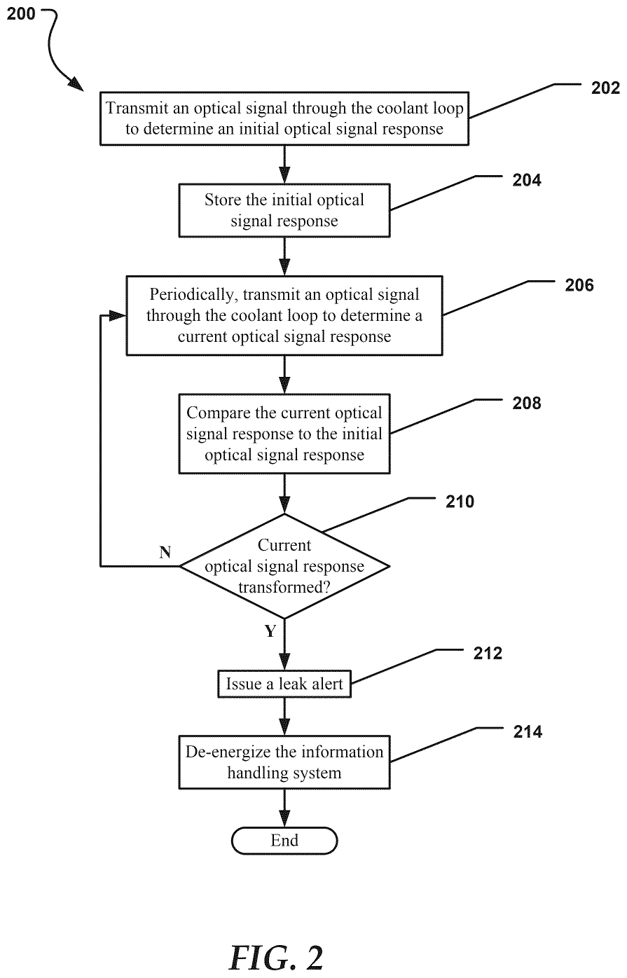

FIG. 2 is a flow diagram of a method 200 for monitoring liquid coolant in an information handling system using the optical light source 130 and the optical light sensor 132 according to at least one embodiment of the present disclosure, starting at block 202. It will be readily appreciated that not every method step set forth in this flow diagram is always necessary, and that certain steps of the methods may be combined, performed simultaneously, in a different order, or perhaps omitted, without varying from the scope of the disclosure. The method steps depicted in FIG. 2 may be executed, or employed in whole, or in part, by the baseboard management controller 112, the CPU 108 of the information handling system 104, a combination thereof, or any other type of controller, device, module, processor, or any combination thereof, operable to employ, or otherwise execute, all, or portions of, the method 200 of FIG. 2.

Beginning at block 202, the method 200 may include transmitting an optical signal through the coolant loop, e.g., through the cooling plate 120 and the associated plumbing, to determine an initial, or nominal, optical signal response For example, the optical light sensor 130 may transmit a light signal through the coolant loop, the light signal is reflected by the liquid coolant in the coolant loop, and is detected by the optical light sensor 132. This is the initial optical signal response. At block 204, the method 200 may include storing the initial optical signal response in the memory 110.

Moving to block 206, the method 200 may include periodically transmitting a current optical signal through the coolant loop, in a manner as described above, to determine a current optical signal response. Then, at block 208, the method 200 may include comparing the current optical signal response to the initial optical signal response. At decision 210, the method 200 may include determining whether the current optical signal response is transformed from the initial optical signal response. If the current optical signal response is transformed from the initial optical signal response, the method 200 may return to block 206 and the method 200 may continue as described herein. On the other hand, at decision 210, if the current optical signal response is transformed from the initial optical signal response, the method 200 may continue to block 212 and the method 200 may include issuing a leak alert. Thereafter, at block 214, the method 200 may include de-energizing the information handling system 104 to prevent, or minimize, damage to the internal components of the information handling system 104. The method 200 may then end.

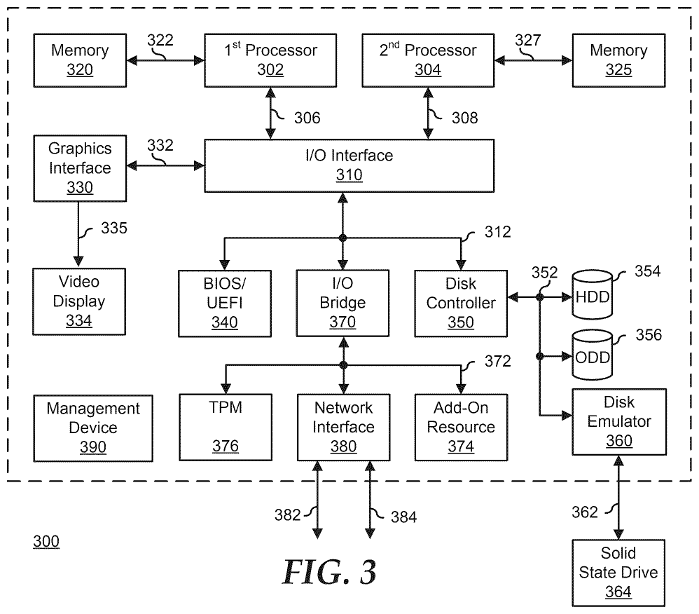

FIG. 3 shows a generalized embodiment of an information handling system 300 according to an embodiment of the present disclosure. Information handling system 300 may be substantially similar to the information handling system 104 of FIG. 1. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 300 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 300 can include processing resources for executing machine-executable code, such as a central processing unit (CPU), a programmable logic array (PLA), an embedded device such as a System-on-a-Chip (SoC), or other control logic hardware. Information handling system 300 can also include one or more computer-readable medium for storing machine-executable code, such as software or data. Additional components of information handling system 300 can include one or more storage devices that can store machine-executable code, one or more communications ports for communicating with external devices, and various input and output (I/O) devices, such as a keyboard, a mouse, and a video display. Information handling system 300 can also include one or more buses operable to transmit information between the various hardware components.

Information handling system 300 can include devices or modules that embody one or more of the devices or modules described below and operates to perform one or more of the methods described herein. Information handling system 300 includes a processors 302 and 304, an input/output (I/O) interface 310, memories 320 and 325, a graphics interface 330, a basic input and output system/universal extensible firmware interface (BIOS/UEFI) module 340, a disk controller 350, a hard disk drive (HDD) 354, an optical disk drive (ODD) 356, a disk emulator 360 connected to an external solid state drive (SSD) 364, an I/O bridge 370, one or more add-on resources 374, a trusted platform module (TPM) 376, a network interface 380, a management device 390, and a power supply 395. Processors 302 and 304, I/O interface 310, memory 320, graphics interface 330, BIOS/UEFI module 340, disk controller 350, HDD 354, ODD 356, disk emulator 360, SSD 364, I/O bridge 370, add-on resources 374, TPM 376, and network interface 380 operate together to provide a host environment of information handling system 300 that operates to provide the data processing functionality of the information handling system. The host environment operates to execute machine-executable code, including platform BIOS/UEFI code, device firmware, operating system code, applications, programs, and the like, to perform the data processing tasks associated with information handling system 300.

In the host environment, processor 302 is connected to I/O interface 310 via processor interface 306, and processor 304 is connected to the I/O interface via processor interface 308. Memory 320 is connected to processor 302 via a memory interface 322. Memory 325 is connected to processor 304 via a memory interface 327. Graphics interface 330 is connected to I/O interface 310 via a graphics interface 332 and provides a video display output 336 to a video display 334. In a particular embodiment, information handling system 300 includes separate memories that are dedicated to each of processors 302 and 304 via separate memory interfaces. An example of memories 320 and 325 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 340, disk controller 350, and I/O bridge 370 are connected to I/O interface 310 via an I/O channel 312. An example of I/O channel 312 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 310 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 340 includes BIOS/UEFI code operable to detect resources within information handling system 300, to provide drivers for the resources, initialize the resources, and access the resources. BIOS/UEFI module 340 includes code that operates to detect resources within information handling system 300, to provide drivers for the resources, to initialize the resources, and to access the resources.

Disk controller 350 includes a disk interface 352 that connects the disk controller to HDD 354, to ODD 356, and to disk emulator 360. An example of disk interface 352 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 360 permits SSD 364 to be connected to information handling system 300 via an external interface 362. An example of external interface 362 includes a USB interface, an IEEE 3394 (Firewire) interface, a proprietary interface, or a combination thereof. Alternatively, solid-state drive 364 can be disposed within information handling system 300.

I/O bridge 370 includes a peripheral interface 372 that connects the I/O bridge to add-on resource 374, to TPM 376, and to network interface 380. Peripheral interface 372 can be the same type of interface as I/O channel 312 or can be a different type of interface. As such, I/O bridge 370 extends the capacity of I/O channel 312 when peripheral interface 372 and the I/O channel are of the same type, and the I/O bridge translates information from a format suitable to the I/O channel to a format suitable to the peripheral channel 372 when they are of a different type. Add-on resource 374 can include a data storage system, an additional graphics interface, a network interface card (NIC), a sound/video processing card, another add-on resource, or a combination thereof. Add-on resource 374 can be on a main circuit board, on separate circuit board or add-in card disposed within information handling system 300, a device that is external to the information handling system, or a combination thereof.

Network interface 380 represents a NIC disposed within information handling system 300, on a main circuit board of the information handling system, integrated onto another component such as I/O interface 310, in another suitable location, or a combination thereof. Network interface device 380 includes network channels 382 and 384 that provide interfaces to devices that are external to information handling system 300. In a particular embodiment, network channels 382 and 384 are of a different type than peripheral channel 372 and network interface 380 translates information from a format suitable to the peripheral channel to a format suitable to external devices. An example of network channels 382 and 384 includes InfiniBand channels, Fibre Channel channels, Gigabit Ethernet channels, proprietary channel architectures, or a combination thereof. Network channels 382 and 384 can be connected to external network resources (not illustrated). The network resource can include another information handling system, a data storage system, another network, a grid management system, another suitable resource, or a combination thereof.

Management device 390 represents one or more processing devices, such as a dedicated baseboard management controller (BMC) System-on-a-Chip (SoC) device, one or more associated memory devices, one or more network interface devices, a complex programmable logic device (CPLD), and the like, which operate together to provide the management environment for information handling system 300. In particular, management device 390 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 300, such as system cooling fans and power supplies. Management device 390 can include a network connection to an external management system, and the management device can communicate with the management system to report status information for information handling system 300, to receive BIOS/UEFI or system firmware updates, or to perform other task for managing and controlling the operation of information handling system 300.

Management device 390 can operate off of a separate power plane from the components of the host environment so that the management device receives power to manage information handling system 300 when the information handling system is otherwise shut down. An example of management device 390 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 390 may further include associated memory devices, logic devices, security devices, or the like, as needed, or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

What is claimed is:

1. A system comprising:
an optical light source to transmit an initial optical signal through a coolant loop;
an optical light sensor to receive an initial optical signal response;
an information handling system comprising:
a memory to communicate with the optical light sensor to store the initial optical signal response;
a processor to communicate with the memory and the optical light sensor, the processor to:
determine a current optical signal response through the coolant loop; and
compare the current optical signal response to the initial optical signal response.

1. The system of claim 1, wherein the processor further to:
determine whether the current optical signal response has transformed from the initial optical signal response.

2. The system of claim 2, wherein the processor further to:
issue a leak alert when the current optical signal response is determined to be transformed.

3. The system of claim 3, wherein the current optical signal response is determined to be transformed when a current phase of the current optical signal response is different from an initial phase of the initial optical signal response.

4. The system of claim 1, wherein the current optical signal response is determined to be transformed when a current amplitude of the current optical signal response is different from an initial amplitude of the initial optical signal response.

5. The system of claim 3, wherein the processor further to:
de-energize the information handling system.

6. The system of claim 6, wherein the coolant loop comprises:
a cooling plate adjacent the processor, wherein the cooling plate is in fluid communication with a cooling distribution unit that circulates liquid coolant through the cooling plate.

7. The system of claim 7, wherein the optical light source is upstream from the cooling plate.

8. The system of claim 8, wherein the optical light sensor is downstream from the cooling plate.

9. The system of claim 9, wherein the optical light source transmits signals through the cooling plate for detection by the optical light sensor.

10. A method comprising:
determining an initial optical signal value within a coolant loop;
storing, by a processor of an information handling system, the initial optical signal value;
determining a current optical signal value within the coolant loop; and
comparing the current optical signal value to the initial optical signal value.

11. The method of claim 11, further comprising:
determining whether the current optical signal value is transformed from the initial optical signal value.

12. The method of claim 12, further comprising:
issuing a leak alert when the current optical signal value is transformed.

13. The method of claim 13, wherein the current optical signal response is determined to be transformed when a current phase of the current optical signal response is different from an initial phase of the initial optical signal response.

14. The method of claim 14, wherein the current optical signal response is determined to be transformed when a current amplitude of the current optical signal response is different from an initial amplitude of the initial optical signal response.

15. A system comprising:
a cooling distribution unit to circulate a coolant;
a cooling plate in fluid communication with the cooling distribution unit;
an optical light source upstream from the cooling plate;
an optical light sensor downstream from the cooling plate;
an information handling system comprising:
a memory; and
a processor adjacent the cooling plate to communicate with the memory, the optical light source, and the optical light sensor, the processor to:
transmit a first optical signal through the cooling plate from the optical light source to the optical light sensor;
determine an initial optical signal response through the cooling plate;
transmit another optical signal through the cooling plate from the optical light source to the optical light sensor; and
determine a current optical signal response through the cooling plate.

16. The system of claim 16, wherein the processor further to:
compare the current optical signal response to the initial optical signal response.

17. The system of claim 17, wherein the processor further to:
determine whether the current optical signal response has transformed from the initial optical signal response.

19. The system of claim 18, wherein the processor further to:
issue a leak alert when the current optical signal response is determined to be transformed.

20. The system of claim 19, wherein the processor further to:
de-energize the information handling system.
